(19) United States
(12) Patent Application Publication
(10) Pub. No.: US 2023/0157094 A1
(43) Pub. Date: May 18, 2023

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Bo LI, Wuhan, Hubei (CN); Wenxu XIANYU, Wuhan, Hubei (CN)

(21) Appl. No.: 16/975,004

(22) PCT Filed: Jun. 23, 2020
(86) PCT No.: PCT/CN2020/097808

§ 371 Date: Aug. 21, 2020

(30) Foreign Application Priority Data
May 8, 2020 (CN) 202010380505.0

(51) Int. Cl. H10K 59/131; H10K 59/40; G06F 3/041; G06F 3/044; G06F 3/042

(52) U.S. Cl. CPC H10K 59/131; H10K 59/40; G06F 3/04164; G06F 3/0445; G06F 3/0421; G06F 3/0412; G06F 2203/04112

(57) ABSTRACT

A display panel and a display device are provided. The display panel includes an organic light-emitting structure layer, a touch layer, and a driver chip. The touch layer includes a plurality of touch electrodes and a plurality of touch signal lines. One terminal of each of the touch signal lines is connected to one of the touch electrodes.

### TECHNICAL FIELD

The present disclosure relates to a display device technology field, and more particularly to a display panel and a display device.

### BACKGROUND

Since the development of OLED (Organic Light-Emitting Diode) display technology, OLED screens have various advantages, such as low energy consumption, a wide viewing angle, a wide color gamut, and a thin thickness when compared with LCD (Liquid Crystal Display) screens. Accordingly, the OLED screens are popularized rapidly. Currently, touch technology with the OLED display technology mainly includes an add-on touch film bonding scheme and On-Cell technology in which a touch layer is directly fabricated on a thin film encapsulation layer.

In the On-Cell technology, an add-on plate is not required. An optically clear adhesive (OCA) and a touch substrate are removed. As such, a module thickness is effectively decreased, and material cost is saved. The On-Cell technology has significant advantages when compared with the add-on touch technology. In particularly, waves of flexible touch displays emerge in recent years and push the On-Cell technology to develop and break through rapidly. The conventional OLED On-Cell technology is mainly based on mutual capacitance touch technology. However, since a thin film encapsulation layer of a display screen tends to be thinner, a distance between a touch layer and a cathode is getting closer and closer. This brings a great challenge for a touch driver chip. Furthermore, in a conventional pattern design of touch electrodes, since space occupied by touch signal lines is increased with closer to output terminals of lines, sizes of the touch electrode are getting smaller and smaller. Accordingly, touch sensitivity is decreased.

### SUMMARY OF DISCLOSURE

An objective of the present disclosure is to provide a display panel and a display device to solve the problems that noises occur in touch signals and touch sensitivity of a touch layer is not high in the prior art.

To implement the above-mentioned objective, the present disclosure provides a display panel including an organic light-emitting structure layer, a touch layer, and a driver chip. The organic light-emitting structure layer includes a cathode. The touch layer is disposed on the organic light-emitting structure layer.

The touch layer includes a plurality of touch electrodes and a plurality of touch signal lines. The touch electrodes are disposed on the cathode in a matrix. A coupling capacitance is formed between each of the touch electrodes and the cathode. One terminal of each of the touch signal lines is connected to one of the touch electrodes.

The driver chip is disposed at one side of the display panel. The other terminal of each of the touch signal lines is connected to the driver chip. The driver chip is configured to acquire a signal of the coupling capacitance and determine whether a touch operation exists according to a change of the signal of the coupling capacitance.

Further, the touch layer further includes a dielectric layer. The dielectric layer is disposed between the touch electrodes and the touch signal lines.

Further, the organic light-emitting structure layer further includes a light-emitting layer and an encapsulation layer. The cathode is disposed between the light-emitting layer and the touch layer. The encapsulation layer is disposed between the cathode and the touch layer.

Further, the display function layer includes a plurality of sub pixels. The sub pixels are uniformly distributed in the display function layer. A gap is formed between two adjacent ones of the sub pixels.

Further, each of the touch electrodes includes metal mesh lines. An orthographic projection of the metal mesh lines falls within the gap of the display function layer.

Further, each of the touch signal lines is a wave-shaped structure and/or a chain-shaped structure. An orthographic projection of the wave-shaped structure and/or a chain-shaped structure falls within the gap of the display function layer.

Further, each of the touch signal lines includes a first metal line and a second metal line, and each of the touch electrodes is correspondingly connected to the first metal line or the second metal line. A line width of the first metal line is smaller than a line width of the second metal line.

Further, the touch electrodes close to the driver chip are connected to the first metal line, and the touch electrodes far away from the driver chip are connected to the second metal line.

Further, the touch layer further includes a protective layer. The protective layer covers the touch signal lines.

The present disclosure further provides a display device. The display device includes the above-mentioned display panel.

Advantageous effect is described as follows. In the display panel and the display device provided by the embodiments of the present disclosure, the touch electrodes and the touch signal lines are disposed in different layers, thereby reducing signals and effect between the touch electrodes and the touch signal lines, increasing the sensitivity of the touch layer, and enhancing user experience. Furthermore, the touch electrodes and the touch signals in the embodiments of the present disclosure are disposed to avoid the sub pixels which emit light, so that the light emitted by the organic light-emitting structure layer is not blocked, and display of an image is not affected. In the embodiments of the present disclosure, the touch signal lines having different line widths are used according to distances between the touch electrodes and the driver chip, thereby solving the problem that impedance differences are large when lengths of the touch signal lines are different.

### BRIEF DESCRIPTION OF DRAWINGS

To describe the technical solutions of the embodiments of the present disclosure more clearly, the following briefly introduces the accompanying drawings required for describing the embodiments. Apparently, the accompanying drawings in the following description show only some embodiments of the present disclosure, and those skilled in the art may still derive other drawings from these accompanying drawings without creative efforts.

FIG. 1 illustrates a layer structure diagram of a display panel in accordance with Embodiments 1-3 of the present disclosure.

FIG. 2 illustrates a distribution diagram of sub pixels in the display panel in accordance with Embodiments 1-3 of the present disclosure.

FIG. 3 illustrates a distribution diagram of touch electrodes in the display panel in accordance with Embodiments 1-3 of the present disclosure.

FIG. 4 illustrates a structure diagram of a touch electrode and a touch signal line in accordance with Embodiment 1 or 3 of the present disclosure.

FIG. 5 illustrates a structure diagram of a touch electrode and a touch signal line in accordance with Embodiment 2 or 3 of the present disclosure.

Elements in the drawings are numbered as follows:
display panel 1;
organic light-emitting structure layer 100; light-emitting layer 110;
cathode 120; encapsulation layer 130;
sub pixel 140; red sub pixel 141;
blue sub pixel 142; green sub pixel 143;
gap 150;
touch layer 200; touch electrode 210;
touch signal line 220; first metal line 221;
second metal line 222; dielectric layer 230
protective layer 240; driver chip 300.

### DETAILED DESCRIPTION OF EMBODIMENTS

The following description of every embodiment with reference to the accompanying drawings is used to exemplify a specific embodiment, which may be carried out in the present disclosure. The embodiments completely introduce the present disclosure for those skilled in the art, which make technology content clear and understand. The present disclosure embodies through different types of the embodiments. The protection range of the present disclosure is not limited in the embodiments of the present disclosure.

In the drawings, the components having similar structures are denoted by the same numerals. The structures and the components have similar function can use similar numerals to express. Thicknesses and sizes of the components in the drawings are randomly shown. The present disclosure does not limit to the thicknesses and the sizes of the components in the drawings. In order to make the drawings clear, the thicknesses of some components in the drawings are properly increased.

Additionally, description will be given by the preferred embodiments along with the accompanied drawings. It can be used to implement a specific embodiment. Direction terms are mentioned in the present disclosure, for example, “upper”, “lower”, “front”, “back”, “left”, “right”, “inside”, “outside”, “side” and so on, only refer to the direction of accompanied drawings. Thus, it is better and clearer to describe and understand the present invention by using direction terms, rather than implying the devices or elements are referred to a specific direction, and a structure or an operation with a specific direction. Therefore, it cannot be understood the limit of the present disclosure. Furthermore, terms “first”, “second”, “third” and the like are only are only for the purpose of description and are not to be construed as indicating or implicit relative importance.

When a certain component is described to be “on” another component, the component may be located directly on the another component. Also, there may exist an intermediate component, the component is located on the intermediate component, and the intermediate component is located on the another component. When a certain component is described to be “mounted on” or “connected to” another component, it may be construed to be directly “mounted on” or directly “connected to”. Alternatively, the component is “mounted on” or “connected to” the another component via an intermediate component.

### Embodiment 1

An embodiment of the present disclosure provides a display device. The display device includes a display panel 1. The display panel 1 provides a display image for the display device. The display device may be a display apparatus with a display function, for example, a mobile phone, a laptop, or a television.

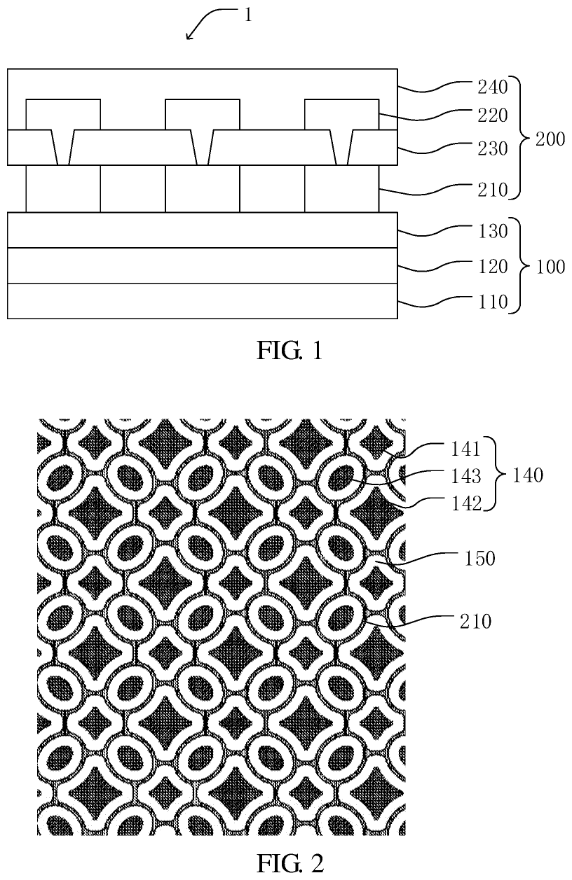

As shown in FIG. 1, the display panel 1 includes an organic light-emitting structure layer 100, a touch layer 200, and a driver chip 300. The touch layer 200 is disposed on one surface of the organic light-emitting structure layer 100. The driver chip 300 is electrically coupled to the touch layer 200.

The organic light-emitting structure layer includes a light-emitting layer 110, a cathode 120, and an encapsulation layer 130. The light-emitting layer 110 includes a plurality of organic electroluminescent devices. The organic electroluminescent devices provide a light source for the display panel 1 to form a display image. The cathode 120 covers the light-emitting layer 110 and provides power for the light-emitting layer 110 to activate the organic electroluminescent devices to emit light. The encapsulation layer 130 is disposed to cover one surface of the cathode 120 far away from the light-emitting layer 110. The encapsulation layer 130 adopts thin-film encapsulation (TFE) technology and is usually a sandwich-type encapsulation structure including an inorganic-organic-inorganic form. In this structure, inorganic layers guarantee stronger densification to block water and oxygen, and an organic layer guarantees flexibility of the display panel 1 to avoid the problem that the inorganic layers have cracks and peel off.

As shown in FIG. 2, the organic light-emitting structure layer 100 further includes a plurality of sub pixels 140. Each of the sub pixels 140 includes a red sub pixel 141, a blue sub pixel 142, and a green sub pixel 143 which are uniformly distributed in the light-emitting layer 110. The organic electroluminescent devices in the red sub pixels 141 can emit red light. The organic electroluminescent devices in the blue sub pixels 142 can emit blue light. The organic electroluminescent devices in the green sub pixels 143 can emit green light. The display panel 1 adopts the trichromatic theory to use the red light emitted by the red sub pixels 141, the blue light emitted by the blue sub pixels 142, the green light emitted by the green sub pixels 143 to form an image display panel. A gap 150 is formed between two adjacent ones of the sub pixels 140. The gap 150 does not have a light-emitting function and is configured to separate the two adjacent ones of the sub pixels 140.

As shown in FIG. 1, the touch layer 200 includes a plurality of touch electrodes 210 and a plurality of touch signal lines 220. The touch signal lines 220 are disposed on one surface of the touch electrodes 210 far away from the encapsulation layer 130 and configured to sense touch signals. One terminal of each of the touch signal lines 220 is connected to one of the touch electrodes 210, and the other terminal of each of the touch signal lines 220 is connected to the driver chip 300. Each of the touch electrodes 210 is connected to a corresponding one of the touch signal lines 220. The touch signals are configured to transmit the touch signals senses by the touch electrodes 210.

In the embodiment of the present disclosure, the touch signal lines 220 are positioned on one surface of the touch electrodes 210 far away from the organic light-emitting structure layer 100. However, in any other embodiment or embodiments, the present disclosure further provides a display panel and a display device which include touch signal lines 220 disposed between the touch electrodes 210 and the organic light-emitting structure layer 100. Remaining layers and a connection structure are similar to the display panel 1 in Embodiment 1 of the present disclosure and thus not repeated herein. All other embodiments obtained by those skilled in the art based on the described embodiments of the present disclosure without the need for creative work are within the protection scope of the present disclosure.

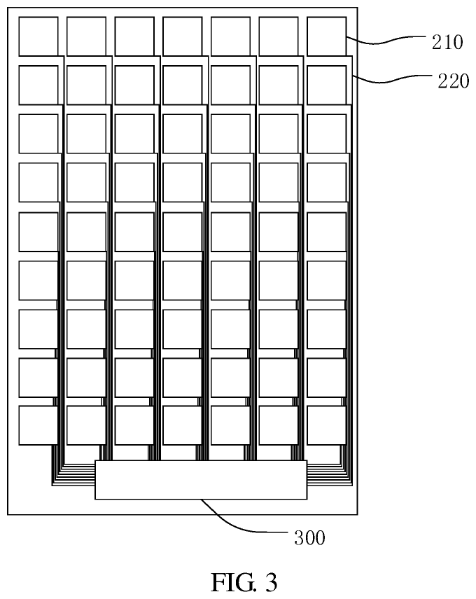

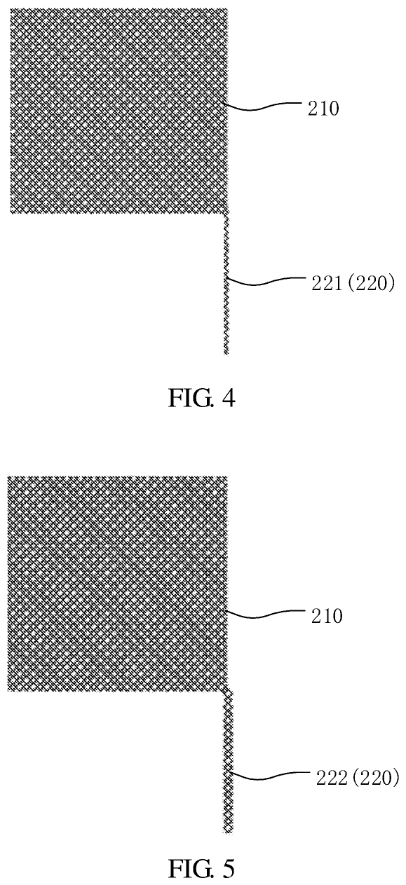

As shown in FIG. 3, the touch electrodes 210 are disposed on the organic light-emitting structure layer 100 in a matrix. A width of each of the touch electrodes 210 is smaller than or equal to 7 millimeters (mm). Sizes of the touch electrodes 210 are uniform to guarantee sensitivity and accuracy. As shown in FIG. 4, each of the touch electrodes 210 includes metal mesh lines. Each of the touch signal lines 220 is a wave-shaped structure. As shown in FIG. 2, an orthographic projection of each of the lines of the touch electrodes 210 and an orthographic projection of each of the touch signal lines 220 fall within the gaps 150 of a display function layer. The lines of the touch electrodes 210 and the touch signal lines 220 are disposed in peripheries of the sub pixels 140 and do not block the sub pixels 140, so that luminous efficiency of the organic light-emitting structure layer 100 is not affected. Furthermore, since the touch electrodes 210 are formed by the metal mesh lines, areas overlapped by the touch signal lines 220 and the touch electrodes 210 are quite small. As such, generated noises are small and do not interfere signal senses of the touch electrodes 210, so that touch sensitivity can be further increased.

The touch layer 200 further includes a dielectric layer 230 and a protective layer 240. As shown in FIG. 1, the dielectric layer 230 is disposed between the touch electrodes 210 and the touch signal lines 220 and configured to insulate the touch electrodes 210. The touch signal lines 220 penetrate the dielectric layer 230 to connect to the touch electrodes 210. The dielectric layer 230 includes an organic photoresist material, so that interference signals can be reduced when the touch signal lines 220 overlap with the touch electrodes 210. The protective layer 240 covers the touch signal lines 220 and the dielectric layer 230 and is configured to insulate the touch signal lines 220. The protective layer 240 includes an organic photoresist material or an inorganic material including at least one of silicon nitride and silica.

The driver chip 300 is disposed at one side of the display panel 1. Each of the touch electrodes 210 independently leads to one of the touch signal lines 220 connected to the driver chip 300. A coupling capacitance is formed between each of the touch electrodes 210 and the cathode 120 of the organic light-emitting structure layer 100. The driver chip 300 is configured to acquire a signal of the coupling capacitance and determine whether a touch operation exists according to a change of the signal of the coupling capacitance.

In the display panel 1 and the display device provided by the embodiments of the present disclosure, the touch electrodes 210 and the touch signal lines 220 are disposed in different layers, thereby reducing signals and effect between the touch electrodes 210 and the touch signal lines 220, increasing the sensitivity of the touch layer 200, and enhancing user experience. Furthermore, the touch electrodes 210 and the touch signals in the embodiments of the present disclosure are disposed to avoid the sub pixels 140 which emit light, so that the light emitted by the organic light-emitting structure layer 100 is not blocked, and display of an image is not affected.

### Embodiment 2

An embodiment of the present disclosure provides a display device. The display device includes a display panel 1. The display panel 1 provides a display image for the display device. The display device may be a display apparatus with a display function, for example, a mobile phone, a laptop, or a television.

As shown in FIG. 1, the display panel 1 includes an organic light-emitting structure layer 100, a touch layer 200, and a driver chip 300. The touch layer 200 is disposed on one surface of the organic light-emitting structure layer 100. The driver chip 300 is electrically coupled to the touch layer 200.

The organic light-emitting structure layer 100 includes a light-emitting layer 110, a cathode 120, and an encapsulation layer 130. The light-emitting layer 110 includes a plurality of organic electroluminescent devices. The organic electroluminescent devices provide a light source for the display panel 1 to form a display image. The cathode 120 covers the light-emitting layer 110 and provides power for the light-emitting layer 110 to activate the organic electroluminescent devices to emit light. The encapsulation layer 130 is disposed to cover one surface of the cathode 120 far away from the light-emitting layer 110. The encapsulation layer 130 adopts thin-film encapsulation (TFE) technology and is usually a sandwich-type encapsulation structure including an inorganic-organic-inorganic form. In this structure, inorganic layers guarantee stronger densification to block water and oxygen, and an organic layer guarantees flexibility of the display panel 1 to avoid the problem that the inorganic layers have cracks and peel off.

As shown in FIG. 2, the organic light-emitting structure layer 100 further includes a plurality of sub pixels 140. Each of the sub pixels 140 includes a red sub pixel 141, a blue sub pixel 142, and a green sub pixel 143 which are uniformly distributed in the light-emitting layer 110. The organic electroluminescent devices in the red sub pixels 141 can emit red light. The organic electroluminescent devices in the blue sub pixels 142 can emit blue light. The organic electroluminescent devices in the green sub pixels 143 can emit green light. The display panel 1 adopts the trichromatic theory to use the red light emitted by the red sub pixels 141, the blue light emitted by the blue sub pixels 142, the green light emitted by the green sub pixels 143 to form an image display panel. A gap 150 is formed between two adjacent ones of the sub pixels 140. The gap 150 does not have a light-emitting function and is configured to separate the two adjacent ones of the sub pixels 140.

As shown in FIG. 1, the touch layer 200 includes a plurality of touch electrodes 210 and a plurality of touch signal lines 220. The touch signal lines 220 are disposed on one surface of the touch electrodes 210 far away from the encapsulation layer 130 and configured to sense touch signals. One terminal of each of the touch signal lines 220 is connected to one of the touch electrodes 210, and the other terminal of each of the touch signal lines 220 is connected to the driver chip 300. Each of the touch electrodes 210 is connected to a corresponding one of the touch signal lines 220. The touch signals are configured to transmit the touch signals senses by the touch electrodes 210.

In the embodiment of the present disclosure, the touch signal lines 220 are positioned on one surface of the touch electrodes 210 far away from the organic light-emitting structure layer 100. However, in any other embodiment or embodiments, the present disclosure further provides a display panel and a display device which include touch signal lines 220 disposed between the touch electrodes 210 and the organic light-emitting structure layer 100. Remaining layers and a connection structure are similar to the display panel 1 in Embodiment 1 of the present disclosure and thus not repeated herein. All other embodiments obtained by those skilled in the art based on the described embodiments of the present disclosure without the need for creative work are within the protection scope of the present disclosure.

As shown in FIG. 3, the touch electrodes 210 are disposed on the organic light-emitting structure layer 100 in a matrix. A width of each of the touch electrodes 210 is smaller than or equal to 7 millimeters (mm). Sizes of the touch electrodes 210 are uniform to guarantee sensitivity and accuracy. As shown in FIG. 5, each of the touch electrodes 210 includes metal mesh lines. Each of the touch signal lines 220 is a chain-shaped structure. As shown in FIG. 2, an orthographic projection of each of the lines of the touch electrodes 210 and an orthographic projection of each of the touch signal lines 220 fall within the gaps 150 of a display function layer. The lines of the touch electrodes 210 and the touch signal lines 220 are disposed in peripheries of the sub pixels 140 and do not block the sub pixels 140, so that luminous efficiency of the organic light-emitting structure layer 100 is not affected. Furthermore, since the touch electrodes 210 are formed by the metal mesh lines, areas overlapped by the touch signal lines 220 and the touch electrodes 210 are quite small. As such, generated noises are small and do not interfere signal senses of the touch electrodes 210, so that touch sensitivity can be further increased.

The touch layer 200 further includes a dielectric layer 230 and a protective layer 240. As shown in FIG. 1, the dielectric layer 230 is disposed between the touch electrodes 210 and the touch signal lines 220 and configured to insulate the touch electrodes 210. The touch signal lines 220 penetrate the dielectric layer 230 to connect to the touch electrodes 210. The dielectric layer 230 includes an organic photoresist material, so that interference signals can be reduced when the touch signal lines 220 overlap with the touch electrodes 210. The protective layer 240 covers the touch signal lines 220 and the dielectric layer 230 and is configured to insulate the touch signal lines 220. The protective layer 240 includes an organic photoresist material or an inorganic material including at least one of silicon nitride and silica.

The driver chip 300 is disposed at one side of the display panel 1. Each of the touch electrodes 210 independently leads to one of the touch signal lines 220 connected to the driver chip 300. A coupling capacitance is formed between each of the touch electrodes 210 and the cathode 120 of the organic light-emitting structure layer 100. The driver chip 300 is configured to acquire a signal of the coupling capacitance and determine whether a touch operation exists according to a change of the signal of the coupling capacitance.

In the display panel 1 and the display device provided by the embodiments of the present disclosure, the touch electrodes 210 and the touch signal lines 220 are disposed in different layers, thereby reducing signals and effect between the touch electrodes 210 and the touch signal lines 220, increasing the sensitivity of the touch layer 200, and enhancing user experience. Furthermore, the touch electrodes 210 and the touch signals in the embodiments of the present disclosure are disposed to avoid the sub pixels 140 which emit light, so that the light emitted by the organic light-emitting structure layer 100 is not blocked, and display of an image is not affected.

### Embodiment 3

An embodiment of the present disclosure provides a display device. The display device includes a display panel 1. The display panel 1 provides a display image for the display device. The display device may be a display apparatus with a display function, for example, a mobile phone, a laptop, or a television.

As shown in FIG. 1, the display panel 1 includes an organic light-emitting structure layer 100, a touch layer 200, and a driver chip 300. The touch layer 200 is disposed on one surface of the organic light-emitting structure layer 100. The driver chip 300 is electrically coupled to the touch layer 200.

The organic light-emitting structure layer 100 includes a light-emitting layer 110, a cathode 120, and an encapsulation layer 130. The light-emitting layer 110 includes a plurality of organic electroluminescent devices. The organic electroluminescent devices provide a light source for the display panel 1 to form a display image. The cathode 120 covers the light-emitting layer 110 and provides power for the light-emitting layer 110 to activate the organic electroluminescent devices to emit light. The encapsulation layer 130 is disposed to cover one surface of the cathode 120 far away from the light-emitting layer 110. The encapsulation layer 130 adopts thin-film encapsulation (TFE) technology and is usually a sandwich-type encapsulation structure including an inorganic-organic-inorganic form. In this structure, inorganic layers guarantee stronger densification to block water and oxygen, and an organic layer guarantees flexibility of the display panel 1 to avoid the problem that the inorganic layers have cracks and peel off.

As shown in FIG. 2, the organic light-emitting structure layer 100 further includes a plurality of sub pixels 140. Each of the sub pixels 140 includes a red sub pixel 141, a blue sub pixel 142, and a green sub pixel 143 which are uniformly distributed in the light-emitting layer 110. The organic electroluminescent devices in the red sub pixels 141 can emit red light. The organic electroluminescent devices in the blue sub pixels 142 can emit blue light. The organic electroluminescent devices in the green sub pixels 143 can emit green light. The display panel 1 adopts the trichromatic theory to use the red light emitted by the red sub pixels 141, the blue light emitted by the blue sub pixels 142, the green light emitted by the green sub pixels 143 to form an image display panel. A gap 150 is formed between two adjacent ones of the sub pixels 140. The gap 150 does not have a light-emitting function and is configured to separate the two adjacent ones of the sub pixels 140.

As shown in FIG. 1, the touch layer 200 includes a plurality of touch electrodes 210 and a plurality of touch signal lines 220. The touch signal lines 220 are disposed on one surface of the touch electrodes 210 far away from the encapsulation layer 130 and configured to sense touch signals. One terminal of each of the touch signal lines 220 is connected to one of the touch electrodes 210, and the other terminal of each of the touch signal lines 220 is connected to the driver chip 300. Each of the touch electrodes 210 is connected to a corresponding one of the touch signal lines 220. The touch signals are configured to transmit the touch signals senses by the touch electrodes 210.

In the embodiment of the present disclosure, the touch signal lines 220 are positioned on one surface of the touch electrodes 210 far away from the organic light-emitting structure layer 100. However, in any other embodiment or embodiments, the present disclosure further provides a display panel and a display device which include touch signal lines 220 disposed between the touch electrodes 210 and the organic light-emitting structure layer 100. Remaining layers and a connection structure are similar to the display panel 1 in Embodiment 1 of the present disclosure and thus not repeated herein. All other embodiments obtained by those skilled in the art based on the described embodiments of the present disclosure without the need for creative work are within the protection scope of the present disclosure.

As shown in FIG. 3, the touch electrodes 210 are disposed on the organic light-emitting structure layer 100 in a matrix. A width of each of the touch electrodes 210 is smaller than or equal to 7 millimeters (mm). Sizes of the touch electrodes 210 are uniform to guarantee sensitivity and accuracy. As shown in FIG. 4 and FIG. 5, each of the touch electrodes 210 includes metal mesh lines. Each of the touch signal lines 220 includes a first metal line 221 and a second metal line 222, and each of the touch electrodes 210 is correspondingly connected to the first metal line 221 or the second metal line 222. As shown in FIG. 4, the first metal line 221 is a wave-shaped structure. As shown in FIG. 5, the second metal line 222 is a chain-shaped structure. A line width of the first metal line 221 is smaller than a line width of the second metal line 222. The touch electrodes 210 close to the driver chip 300 are connected to the first metal line 221, and the touch electrodes 210 far away from the driver chip 300 are connected to the second metal line 222.

As shown in FIG. 5, an orthographic projection of each of the lines of the touch electrodes 210 and an orthographic projection of each of the touch signal lines 220 fall within the gaps 150 of a display function layer. The lines of the touch electrodes 210 and the touch signal lines 220 are disposed in peripheries of the sub pixels 140 and do not block the sub pixels 140, so that luminous efficiency of the organic light-emitting structure layer 100 is not affected. Furthermore, since the touch electrodes 210 are formed by the metal mesh lines, areas overlapped by the touch signal lines 220 and the touch electrodes 210 are quite small. As such, generated noises are small and do not interfere signal senses of the touch electrodes 210, so that touch sensitivity can be further increased.

The touch layer 200 further includes a dielectric layer 230 and a protective layer 240. As shown in FIG. 1, the dielectric layer 230 is disposed between the touch electrodes 210 and the touch signal lines 220 and configured to insulate the touch electrodes 210. The touch signal lines 220 penetrate the dielectric layer 230 to connect to the touch electrodes 210. The dielectric layer 230 includes an organic photoresist material, so that interference signals can be reduced when the touch signal lines 220 overlap with the touch electrodes 210. The protective layer 240 covers the touch signal lines 220 and the dielectric layer 230 and is configured to insulate the touch signal lines 220. The protective layer 240 includes an organic photoresist material or an inorganic material including at least one of silicon nitride and silica.

The driver chip 300 is disposed at one side of the display panel 1. Each of the touch electrodes 210 independently leads to one of the touch signal lines 220 connected to the driver chip 300. A coupling capacitance is formed between each of the touch electrodes 210 and the cathode 120 of the organic light-emitting structure layer 100. The driver chip 300 is configured to acquire a signal of the coupling capacitance and determine whether a touch operation exists according to a change of the signal of the coupling capacitance.

In the display panel 1 and the display device provided by the embodiments of the present disclosure, the touch electrodes 210 and the touch signal lines 220 are disposed in different layers, thereby reducing signals and effect between the touch electrodes 210 and the touch signal lines 220, increasing the sensitivity of the touch layer 200, and enhancing user experience. Furthermore, the touch electrodes 210 and the touch signals in the embodiments of the present disclosure are disposed to avoid the sub pixels 140 which emit light, so that the light emitted by the organic light-emitting structure layer 100 is not blocked, and display of an image is not affected. In the embodiments of the present disclosure, the touch signal lines 220 having different line widths are used according to distances between the touch electrodes 210 and the driver chip 300, thereby solving the problem that impedance differences are large when lengths of the touch signal lines 220 are different.

Although the present disclosure is described with reference to specific embodiments, it can be understood that these embodiments are merely examples of the principles and applications of the present disclosure. Hence, it can be understood that numerous modifications can be made to the embodiments, and other arrangements can be made, as long as they do not go beyond the spirit and scope of the present disclosure as defined by the appended claims. It can be understood that different dependent claims and features described herein can be combined in a manner different from those described in the initial claims. It can also be understood that the technical features described in one embodiment can also be used in other embodiments.

What is claimed is:

1. A display panel, comprising:
an organic light-emitting structure layer comprising a cathode;
a touch layer disposed on the organic light-emitting structure layer, wherein the touch layer comprises:
a plurality of touch electrodes disposed on the cathode in a matrix, wherein a coupling capacitance is formed between each of the touch electrodes and the cathode; and
a plurality of touch signal lines, wherein one terminal of each of the touch signal lines connected to one of the touch electrodes; and
a driver chip disposed at one side of the display panel, wherein the other terminal of each of the touch signal lines is connected to the driver chip, and the driver chip is configured to acquire a signal of the coupling capacitance and determine whether a touch operation exists according to a change of the signal of the coupling capacitance.

2. The display panel of claim 1, wherein the touch layer further comprises:
a dielectric layer disposed between the touch electrodes and the touch signal lines.

3. The display panel of claim 1, wherein the organic light-emitting structure layer further comprises:
a light-emitting layer, wherein the cathode is disposed between the light-emitting layer and the touch layer; and
an encapsulation layer disposed between the cathode and the touch layer.

4. The display panel of claim 1, wherein the display function layer comprises a plurality of sub pixels, and the sub pixels are uniformly distributed in the display function layer;
wherein a gap is formed between two adjacent ones of the sub pixels.

5. The display panel of claim 2, wherein each of the touch electrodes comprises metal mesh lines, and an orthographic projection of the metal mesh lines falls within the gap of the display function layer.

6. The display panel of claim 2, wherein each of the touch signal lines is a wave-shaped structure and/or a chain-shaped structure, and an orthographic projection of the wave-shaped structure and/or a chain-shaped structure falls within the gap of the display function layer.

7. The display panel of claim 2, wherein each of the touch signal lines comprises a first metal line and a second metal line, and each of the touch electrodes is correspondingly connected to the first metal line or the second metal line;
wherein a line width of the first metal line is smaller than a line width of the second metal line.

8. The display panel of claim 5, wherein the touch electrodes close to the driver chip are connected to the first metal line, and the touch electrodes far away from the driver chip are connected to the second metal line.

9. The display panel of claim 1, wherein the touch layer further comprises:
a protective layer covering the touch signal lines.

10. A display device, comprising the display panel of claim 1.
